(19) United States
(12) Patent Application Publication
(10) Pub. No.: US 2005/0109916 A1
(43) Pub. Date: May 26, 2005

(54) Large pixel micro-lens

(75) Inventor: Christopher Parks, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 10/719,568

(22) Filed: Nov. 21, 2003

(51) Int. Cl. H01L 27/00; H01J 5/16

(52) U.S. Cl. 250/208.1; 250/216

(57) ABSTRACT

An image sensor includes a photosensitive area that receives incident light for detecting photons; and at least one micro-lens that substantially spans a peripheral region of the photosensitive area, and the at least one micro-lens does not span a central portion of photosensitive area for focusing light from outside the peripheral region to the photosensitive area.

### FIELD OF THE INVENTION

The invention relates generally to the field of micro-lens for image sensors having large pixels and, more particularly, to such micro-lens that substantially spans only a peripheral region of the large pixel.

### BACKGROUND OF THE INVENTION

In general terms, an image sensor consists of an array of pixels fabricated on a substrate. Each pixel 6, shown as prior art in FIG. 1, consists of a photosensitive region 1 of the substrate and a non-photoactive region 2 of the substrate. The non-photoactive region 2 exists for charge transport structures on charge coupled device (CCD) type image sensors. The non-photoactive region 2 may also be used for charge sensing circuitry in the case of CMOS or active pixel type image sensors. The sensitivity of the pixel is increased by diverting light rays 5 that are directed away from the non-photoactive region 2 towards the photosensitive region 1. This is typically done with a micro-lens 4 type structure as described in U.S. Pat. No. 4,667,092. The micro-lens 4 is some transparent material formed into a focusing element held above the surface of the substrate by one or more transparent spacer layers 3. There are many patented variations of the prior art in FIG. 1 that add such elements as mirrors (U.S. Pat. No. 5,172,206), multiple lens elements (U.S. Pat. No. 5,371,397), or planar overcoat layers (U.S. Pat. No. 5,239,412).

A significant disadvantage to prior art methods and apparatus exists when they are applied to large pixels. Current manufacturing processes for CCD or CMOS image sensors have a limited range for the thickness of the micro-lens, t₂, and the spacer layer, t₁. When the pixel size exceeds 10 μm, the light collection efficiency of the micro-lens decreases. Referring to FIG. 2, the pixel is shown with the typical maximum layer thickness t₁ and t₂ as fabricated by standard manufacturing processes. Each layer thickness is too thin to properly divert light towards the photosensitive region. The standard manufacturing processes typically use spin on coatings or deposited layers that have upper thickness limits in the range of 4 to 5 μm. Thicker coatings are possible, but they require the addition of specialized equipment and processes that are more difficult to control.

Consequently, a need exists for a new micro-lens structure that improves the light collection efficiency of a large pixel by employing the same manufacturing processes of small pixels.

### SUMMARY OF THE INVENTION

The present invention is directed to overcoming one or more of the problems set forth above. Briefly summarized, according to one aspect of the present invention, the invention resides in an image sensor having a photosensitive area that receives incident light for detecting photons; at least one micro-lens that substantially spans a peripheral region of the photosensitive area, and the at least one micro-lens does not span a central portion of photosensitive area for focusing light from outside the peripheral region to the photosensitive area.

These and other aspects, objects, features and advantages of the present invention will be more clearly understood and appreciated from a review of the following detailed description of the preferred embodiments and appended claims, and by reference to the accompanying drawings.

Advantageous Effect Of The Invention

The present invention has the following advantage of a micro-lens structure for large pixels that improves the light collection efficiency of a large pixel by employing the same manufacturing processes of small pixels

### BRIEF DESCRIPTION OF THE DRAWINGS

FIG. 1 is a cross sectional view of a prior art small pixel and its associated micro-lens;

FIG. 2 is a cross sectional view of a prior art large pixel and its associated micro-lens;

FIG. 3 is a cross sectional view of a large pixel and its associated micro-lens of the present invention;

FIG. 4 is a top view of FIG. 3;

FIG. 5 is a top view of the image sensor of the present invention; and

FIG. 6 is a side view of a camera for implementing a typical commercial embodiment for the large pixel and its micro-lens.

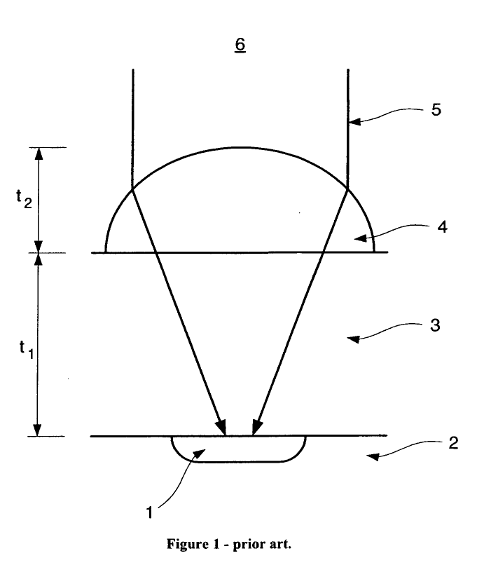

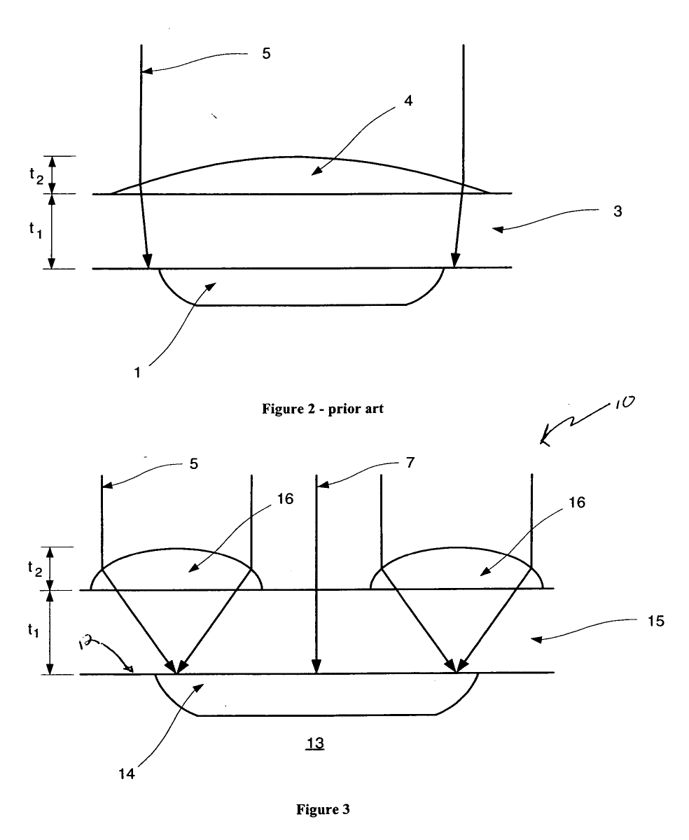

### DETAILED DESCRIPTION OF THE INVENTION

The preferred embodiment of the image sensor 10 (only a portion is shown) of the present invention is shown in FIG. 3. The image sensor 10 having a substrate 13 that includes a plurality of pixels 12 (only one is shown for simplicity) for capturing incident light as is well known in the art. The photosensitive region 14 of the pixel 12 is preferably substantially 10 microns or more in width or length. The spacer layer 15 and lens or micro-lens 16 use the same layer thickness t₁ and t₂ that might be used in fabricating a small pixel. The smaller lens 16 is shaped so that it is positioned around or substantially around the perimeter of the photosensitive region 14; for example, a rectangle (illustrated in the preferred embodiment) or circular shaped lens. In each instance, the lens 16 includes a hollowed out center portion. It is also noted that two or more lens may be used to have the same shape or configuration as the lens 16 as those skilled in that art will readily recognize. The focal point of the micro-lens is set within the photoactive region.

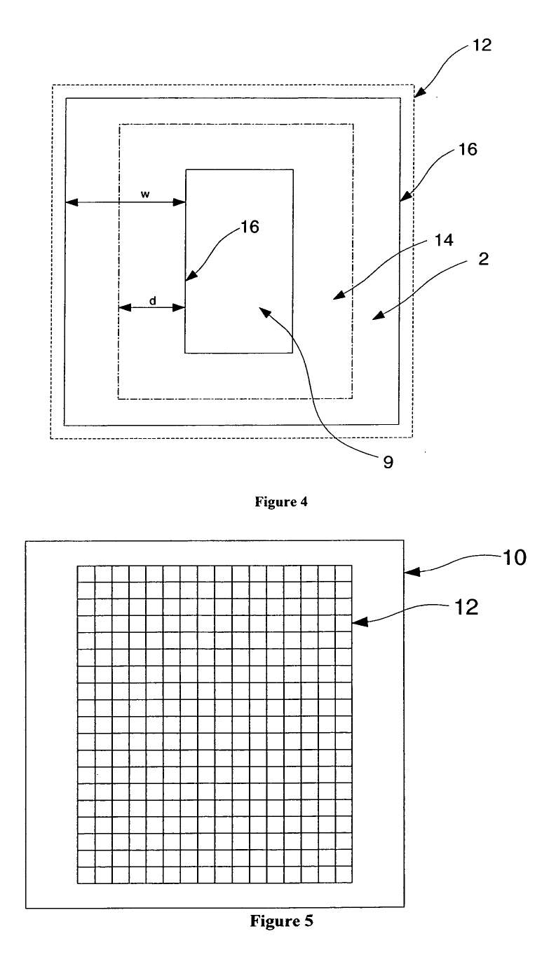

FIG. 4 shows an overhead or top view of the micro-lens 16 from FIG. 3. This shows how the lens 16 outlines the entire perimeter of the photosensitive region 14 with a hollowed out center portion 9. It is instructive to note the width, w, of the lens 16 and the distance, d, between the edge of the micro-lens 16 and the edge of the photosensitive region 14. The value of d is chosen to be greater then w/2 to ensure the focus of the lens is within the photosensitive region 14. It is noted as obvious that the values of d and w may be different on all sides of the pixel depending on the relative location between the photosensitive region 14 and the pixel 12 boundary. The lens 16 does not cover the central portion 9 of the photosensitive region 14. A lens 16 is not required in the central portion 9 because light rays 7 (FIG. 3) will inherently or naturally be incident upon the photosensitive region 14.

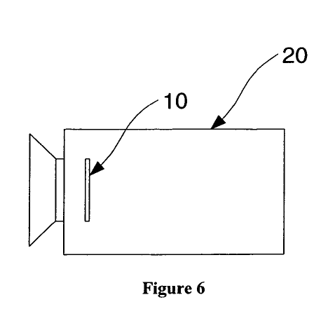

Referring to FIG. 5, there is shown a top view of the image sensor 10 having a plurality of pixels 12 for clarity of understanding.

Referring to FIG. 6, there is shown a camera 20 for implementing a commercial embodiment of the present invention. The sensor of the present invention is installed in the camera for capturing images, and the camera includes other apparatus for processing and storing the captured images.

The invention has been described with reference to a preferred embodiment. However, it will be appreciated that variations and modifications can be effected by a person of ordinary skill in the art without departing from the scope of the invention.

Parts List

1 photosensitive region
2 non-photoactive region
3 transparent spacer layer
4 micro-lens
5 light rays
6 pixel
7 light rays
9 hollowed out center portion
10 image sensor
12 plurality of pixels
13 substrate
14 photosensitive region
15 spacerlayer
16 lens or micro-lens
20 camera

1. An image sensor comprising:
(a) a photosensitive area that receives incident light for detecting photons; and
(b) at least one micro-lens that substantially spans a peripheral region of the photosensitive area, and the at least one micro-lens does not span a central portion of photosensitive area for focusing light from outside the peripheral region to the photosensitive area.

2. The image sensor as in claim 1, wherein the at least one micro-lens is only one micro-lens which is shaped substantially continuous spanning the peripheral region of the photosensitive area and includes a hollowed-out central portion.

3. The image sensor as in claim 1, wherein the photosensitive area is substantially 10 microns or more in width or length.

4. The image sensor as in claim 1, wherein the image sensor is a CMOS or a CCD sensor.

5. A camera comprising:
an image sensor comprising:
(a) a photosensitive area that receives incident light for detecting photons; and
(b) at least one micro-lens that substantially spans a peripheral region of the photosensitive area, and the at least one micro-lens does not span a central portion of photosensitive area for focusing light from outside the peripheral region to the photosensitive area.

6. The camera as in claim 5, wherein the at least one micro-lens is only one micro-lens which is shaped substantially continuous around the peripheral region of the photosensitive area and includes a hollowed-out central portion.

7. The camera as in claim 5, wherein the photosensitive area is substantially 10 microns or more in width or length.

8. The camera as in claim 5, wherein the image sensor is a CMOS or a CCD sensor.
